(19) United States
(12) Patent Application Publication
(10) Pub. No.: US 2025/0362356 A1
(43) Pub. Date: Nov. 27, 2025

(54) SYSTEM AND METHOD FOR DETERMINING A DETERIORATION STATUS OF A SECONDARY BATTERY

(71) Applicant: Prime Planet Energy & Solutions, Inc., Tokyo (JP)

(72) Inventors: Mitsuhiro KUZUBA, Kasugai-shi (JP); Yuya ISHIHARA, Nagoya-shi (JP)

(21) Appl. No.: 19/019,465

(22) Filed: Jan. 14, 2025

(30) Foreign Application Priority Data
May 24, 2024 (JP) 2024-084834

(51) Int. Cl. G01R 31/392; G01R 31/374; G01R 31/3842; H01M 10/42

(52) U.S. Cl. CPC G01R 31/392; G01R 31/374; G01R 31/3842; H01M 10/4285

(57) ABSTRACT

A deterioration status determination system includes a measuring unit that measures the battery temperature, battery current, and battery voltage, a storing unit, a capacity estimating unit that estimates the estimated charge capacity, a conforming discharge period detecting unit that detects a conforming discharge period in which a high C-rate discharge that conforms to discharge conditions is performed, a measured voltage drop acquiring unit that obtains a measured voltage drop amount that appears during the conforming discharge period, an estimated voltage drop acquiring unit that obtains an estimated voltage drop amount that is estimated to appear during the same period, and a determining unit that determines whether there is abnormal deterioration in the battery, from the measured voltage drop amount and the estimated voltage drop amount.

### CROSS-REFERENCE TO RELATED APPLICATIONS

This application is based upon and claims the benefit of priority to Japanese Patent Application No. 2024-084834 filed on May 24, 2024, the entire contents of which are incorporated herein by reference.

### BACKGROUND

### Technical Field

The disclosure relates to a deterioration status determining system and a deterioration status determining method for determining the deterioration status of a secondary battery.

### Related Art

Secondary batteries, such as lithium-ion secondary batteries, deteriorate as they are used. For example, the battery capacity (charge capacity and discharge capacity) gradually decreases as the batteries are used. This type of deterioration is so-called “normal deterioration” that normally occurs in secondary batteries.

In contrast, there are cases where deterioration progresses abnormally due to factors such as the precipitation of lithium. For this type of deterioration, a control system that takes account of the relationship between the deterioration and the amount of lithium precipitation is disclosed in Japanese unexamined patent application publication No. 2018-073777 (JP 2018-073777 A).

### SUMMARY

### Technical Problems

However, there are cases where abnormal deterioration as one form of deterioration occurs which is different from the above-mentioned normal deterioration and the deterioration caused by the lithium precipitation, etc. as described above. The deterioration may take the form of, for example, significant reduction of the salt concentration in the electrolyte, depending on the conditions of use of the secondary battery, such as use at high temperatures or use at high discharge currents. When a secondary battery in which a deterioration phenomenon such as reduction of the salt concentration in the electrolyte occurs is recharged, there is almost no difference in change of the battery voltage, etc., between the secondary battery and a battery with normal deterioration. However, when the secondary battery with the abnormal deterioration is discharged, especially when discharged at a high discharge current, a phenomenon of abnormal voltage drop occurs, that is, the battery voltage drops significantly during discharge, compared to the secondary battery with normal deterioration having the same charge capacity.

However, if the occurrence of the abnormal deterioration in the secondary battery cannot be properly detected, the problem as follows may take place. In devices that use the secondary battery as a driving energy source, for example, in vehicles, such as HEVs, PHEVs, and BEVs, and battery-powered drones using energy stored in the secondary battery for driving or flying, when the battery is discharged at a high current for rapid acceleration or rapid rise, for example, the battery voltage drops significantly and reaches the lower limit voltage early, which may result in a problem that the distance the vehicle or drone can actually travel or fly becomes significantly shorter than the distance that can be traveled or flown and is estimated from the battery voltage and the SOC.

It has been found that, when the secondary battery with normal deterioration is discharged over a certain period of time under starting conditions of the same battery temperature and the same battery voltage, at the same C-rate of discharge current that is obtained by dividing the battery current by the battery capacity (charge capacity) at that point in time, the amount of reduction of the battery voltage at the end of the discharge relative to the battery voltage before the start of the discharge is approximately the same, regardless of the degree of progression of the normal deterioration. On the other hand, it has been found that, when the secondary battery with the above abnormal deterioration is discharged over a certain period of time under starting conditions of the same battery temperature and the same battery voltage as those in the case of normal deterioration, at the same C-rate of discharge current, the amount of reduction of the battery voltage at the end of the discharge relative to the battery voltage before the start of the discharge is larger than that of the secondary battery with normal deterioration.

In this connection, when the secondary battery is discharged over the same period of time, the amount of reduction of the battery voltage is larger as the discharge current is larger, that is, as the C-rate of discharge is higher. In the secondary battery in which the abnormal deterioration has occurred, the amount of reduction of the battery voltage is larger as the C-rate of the discharge current is higher, as compared with the secondary battery with normal deterioration. In particular, when the discharge current is passed through the battery at a high discharge C-rate, for example, in the case of a vehicle-mounted secondary battery, when a discharge current that is 15 times or more greater than the discharge current discharged from the secondary battery while the vehicle is traveling at a constant speed of 60 km/h on a flat road is passed through the battery, the amount of reduction of the battery voltage in the secondary battery in which abnormal deterioration has occurred is greater than that in the secondary battery with normal deterioration. This may be because, when a large discharge current is passed through the secondary battery, the effect of the increase in the diffusion resistance that appears near a positive electrode plate in the secondary battery becomes more noticeable. In a typical example, when a discharge current of 100 A or more flows from the secondary battery, the amount of reduction of the battery voltage is greater in the secondary battery in which abnormal deterioration has occurred than in the secondary battery with normal deterioration.

The disclosure was made in light of the problems and findings, and provides deterioration status determination system and deterioration status determining method that can appropriately detect abnormal deterioration that causes an abnormal voltage drop when a second battery is discharged.

### Means of Solving the Problems

(1) One aspect of the disclosure for solving the above problems is a system for determining a deterioration status of a secondary battery that contains an electrode body impregnated with an electrolyte including a measuring unit that measures a battery temperature, a battery current, and a battery voltage of the secondary battery, a storing unit that stores the battery temperature, the battery current, and the battery voltage that are measured, in chronological order, a capacity estimating unit that estimates the current estimated charge capacity of the secondary battery, a conforming discharge period detecting unit that detects occurrence of a conforming discharge period in which a conforming discharge that conforms to a predetermined set of discharge conditions is performed, using the battery temperature, the battery current, and the battery voltage, a measured voltage drop acquiring unit that obtains a measured voltage drop amount that appears during the detected conforming discharge period, using the battery voltage, an estimated voltage drop acquiring unit that obtains an estimated voltage drop amount that is estimated to appear during the conforming discharge period, using the estimated charge capacity, a duration of the conforming discharge period, the battery temperature during the conforming discharge period, and the battery current flowing during the conforming discharge period, and a determining unit that determines whether there is abnormal deterioration in the secondary battery, from the measured voltage drop amount and the estimated voltage drop amount.

Even when abnormal deterioration, such as a significant reduction of the salt concentration in the electrolyte, occurs in the secondary battery, this has little effect on the behavior of the secondary battery when it is recharged. However, when the secondary battery with the abnormal deterioration is discharged, the battery voltage drops by a larger degree than it would in the case of normal deterioration, at the end of the discharge compared to before the discharge or immediately after the discharge starts. Thus, the deterioration status determination system for the secondary battery obtains the measured voltage drop amount that actually appeared during the conforming discharge period in which the conforming discharge that satisfies the predetermined set of discharge conditions is performed. In addition, the system estimates the estimated voltage drop amount in the case of normal deterioration, using the current estimated charge capacity, and determines whether there is an abnormal voltage drop in the secondary battery from the measured voltage drop amount and the estimated voltage drop amount. Therefore, the system can appropriately determine whether abnormal deterioration that causes an abnormal voltage drop has occurred in the secondary battery.

Examples of the secondary battery include a lithium-ion secondary battery, sodium-ion secondary battery, and so forth. Examples of the electrolyte include a non-aqueous electrolyte obtained by dissolving an electrolyte salt, such as lithium salt or sodium salt, in an organic solvent. The organic solvent may be selected from, for example, cyclic carbonates, such as propylene carbonate and ethylene carbonate, and chain carbonates, such as dimethyl carbonate, diethyl carbonate, and ethyl methyl carbonate. As the electrode body, a wound-type or rolled-type electrode body made by winding strip-shaped positive electrode plate and negative electrode plate together with separators, or a flat would-type electrode body made by flattening the wound-type electrode body, may be used. In addition, a laminate-type electrode body made by laminating sheet-shaped positive electrode plates and negative electrode plates together with separators may also be used.

The capacity estimating unit may estimate the estimated charge capacity by, for example, estimating the charge capacity using the history of the battery temperature of the secondary battery or the time for which the battery is held at each temperature, or estimating the charge capacity of the secondary battery based on the interval charge capacity obtained when partial charging (e.g., charging in the interval from 40% to 50% SOC) is performed on the secondary battery.

The conforming discharge period detecting unit may determine the occurrence of the conforming discharge period by, for example, determining a given test period as the conforming discharge period when the discharge conditions CD are satisfied during the test period, specifically, when all of the following discharge sub-conditions CDa to CDd that make up the set of discharge conditions CD are satisfied. CDa: The SOC of the secondary battery at the start of the test period is within a specified range (e.g., SOC=60±5%). CDb: The average battery temperature during the test period including the start time is within a specified temperature range (e.g., 25±5° C.). CDc: The average C-rate, which is the average value of the C-rate obtained by dividing the battery current discharged from the secondary battery during the test period including the start time by the estimated charge capacity, is within a specified C-rate range (e.g., +20 to +40 C). CDd: The length of the test period in which the above-mentioned discharge sub-conditions CDa to CDd are satisfied has reached a specified duration (e.g., 10 seconds, 15 seconds).

The conforming discharge period detecting unit may use two or more sets of discharge conditions that are different from each other (e.g., two or more sets of discharge sub-conditions of which the contents are different from those of the above-mentioned discharge sub-conditions CDa to CDd) to detect the conforming discharge period corresponding to any set of discharge conditions (any set of discharge sub-conditions). The conforming discharge performed during the conforming discharge period is discharge that satisfies predetermined discharge conditions (for example, the above-mentioned set of discharge sub-conditions CDa to CDd). As the battery current value (C-rate) of the conforming discharge is larger, the condition (see the above-mentioned discharge sub-condition CDd) regarding the length of the conforming discharge period can be set to be shorter in many cases. When charge carriers, such as Li ions, are inserted from the electrolyte into positive electrode active material layers due to discharge of the secondary battery, the concentration of charge carriers, such as the Li ion concentration, in the electrolyte near the positive electrode plate is reduced; therefore, the diffusion resistance is generated, causing a voltage drop. The diffusion resistance is more likely to increase early as the discharge current is larger. On the other hand, the length of the conforming discharge period (corresponding to the specified length of the test period in the discharge sub-condition CDd) is preferably 5 seconds or more. This is because an abnormal voltage drop due to reduction of the salt concentration, for example, occurs significantly when the discharge is continued over a certain period of time (e.g., 5 seconds or more).

The measured voltage drop acquiring unit obtains the measured voltage drop amount using the battery voltage. Specifically, for example, the battery voltage measured at each point in time and stored in the storing unit is used, and the average value of the difference between the battery voltage measured at the start point of the detected conforming discharge period and the battery voltage measured at each point in time during the conforming discharge period in which discharge current flows is set as the measured voltage drop amount.

The “estimated voltage drop amount” is the voltage drop amount estimated to appear during the conforming discharge period when a secondary battery that has not been deteriorated or has undergone normal deterioration, that is, a secondary battery in which deterioration in the form of an abnormal voltage drop has not occurred, is used. The estimated voltage drop acquiring unit acquires the “estimated voltage drop amount” using the estimated charge capacity, the duration of the conforming discharge period, the battery temperature during the conforming discharge period, and the battery current flowing during the conforming discharge period. For example, the conforming discharge that satisfies the discharge conditions (e.g., the above-mentioned discharge sub-conditions CDa to CDd) of the conforming discharge period determined by the conforming discharge period detecting unit is performed on multiple secondary batteries with different charge capacities, which have been deteriorated normally through use or forced deterioration test. At this time, voltage drop amounts that appear in the secondary batteries during the conformed discharge are obtained in advance, and a graph, lookup table, function, or the like, is obtained from the results. Then, the estimated voltage drop acquiring unit may obtain the estimated voltage drop amount, using the graph, lookup table, function, or the like.

The determining unit may determine whether there is an abnormal voltage drop in the manner as follows. The determining unit may calculate the deviation state index, such as the deviation amount (ΔVrnA−ΔVen), the deviation ratio (ΔVrnA/ΔVen), or the deviation rate ((ΔVrnA-ΔVen)/ΔVen), from the measured voltage drop amount ΔVrnA and the estimated voltage drop amount ΔVen, and may determine that an abnormal voltage drop occurs in the secondary battery, namely, deterioration that causes the abnormal voltage drop occurs in the secondary battery, when the calculated value is larger than a predetermined threshold value. The determining unit may also determine the degree or rank of deterioration that causes the abnormal voltage drop, in addition to the presence or absence of the abnormal voltage drop.

(2) In the deterioration status determination system for the secondary battery described in (1) above, the estimated voltage drop acquiring unit may obtain the estimated voltage drop amount, using a linear function equation that is obtained in advance using an average C-rate as a variable. The average C-rate is the average of the C-rate obtained by dividing the battery current by the estimated charge capacity over the conforming discharge period.

When normal deterioration that normally occurs through use occurs in the secondary battery, the battery capacity (charge capacity and discharge capacity) decreases as the normal deterioration progresses from the beginning of use. However, as described above, when the normally deteriorated secondary battery is discharged over a specified discharge period (e.g., 10 seconds) under starting conditions of the same battery temperature and the same battery voltage, at the same C-rate (the battery current divided by the battery capacity (charge capacity)), the amount of reduction of the battery voltage is approximately the same regardless of the degree of progression of normal deterioration. In the case of secondary batteries installed in vehicles, for example, the magnitude of the battery current that flows over a specified discharge period is often not constant. Thus, the C-rate, which is obtained by dividing the battery current by the estimated charge capacity, will be replaced with the average C-rate that is the average of the C-rates over the discharge period. In this case, too, when the normally deteriorated secondary battery is discharged over the specified discharged period under the starting conditions of the same battery temperature and the same battery voltage, at the same average C-rate, the amount of reduction of the battery voltage is approximately the same regardless of the degree of progression of normal deterioration.

As the C-rate or average C-rate of the battery current flowing during the discharge period is larger, the voltage drop amount that appears during the discharge period also increases. Accordingly, when the secondary battery is experiencing normal deterioration, the average C-rate of the battery current flowing during the specified discharge period and the measured voltage drop amount have a relationship that satisfies almost the same linear function equation regardless of the degree of progression of the normal deterioration.

On the other hand, when the secondary battery is experiencing abnormal deterioration due to factors such as a significant reduction of the salt concentration in the electrolyte, the relationship between the average C-rate of the battery current flowing during the specified discharge period and the measured voltage drop amount deviates from the above-mentioned linear function equation, that is, does not satisfy the linear function equation. This is because the measured voltage drop amount becomes larger than that of the secondary battery with normal deterioration.

Thus, since the estimated voltage drop acquiring unit obtains the estimated voltage drop amount, using the predetermined linear function equation using, as a variable, the average C-rate of the battery current flowing during the conforming discharge period that satisfies the discharge conditions, the system can easily determine whether abnormal deterioration has occurred in the secondary battery, based on the difference between the estimated voltage drop amount and the measured voltage drop amount.

(3) In the deterioration status determination system for the secondary battery described in (1) or (2) above, the determining unit may include a deviation state acquiring unit that obtains an index of a deviation state between the estimated voltage drop amount and the measured voltage drop amount, and a deviation state determining unit that determines whether there is the abnormal deterioration based on the obtained index of the deviation state.

In this system, the abnormal deterioration determining unit includes the deviation state acquiring unit that obtains the deviation state index, and the deviation state determining unit that determines whether there is abnormal deterioration based on the deviation state index. As the presence or absence of abnormal deterioration is determined using the deviation state index, the determining process is easy. The deviation state determining unit may also determine the degree or rank of abnormal deterioration, in addition to the presence or absence of abnormal deterioration.

The deviation state index is the index indicating the degree of deviation of the measured voltage drop amount ΔVrnA from the estimated voltage drop amount ΔVen. Examples of the deviation state index include the deviation amount (ΔVrnA−ΔVen), the deviation ratio (ΔVrnA/ΔVen), and the deviation rate ((ΔVrnA−ΔVen)/ΔVen).

(4) In the deterioration status determination system for the secondary battery described in any one of (1) to (3) above, the conforming discharge performed during the conforming discharge period detected by the conforming discharge period detecting unit may be a high-current conforming discharge in which the battery current of 75 A or more on average flows.

In this system, in the high-current conforming discharge performed during the conforming discharge period detected by the conforming discharge period detecting unit, a large battery current of 75 A or more on average is passed through the battery during the conforming discharge period. Therefore, in this system, the “voltage drop amount ΔV” that appears when the secondary battery is experiencing abnormal deterioration is likely to be larger than the “voltage drop amount ΔV” in the case of normal deterioration, making it easier to determine whether there is abnormal deterioration.

(5) Another aspect of the disclosure for solving the above problems is a method for determining a deterioration status of a secondary battery that contains an electrode body impregnated with an electrolyte, including a measuring process of measuring a battery temperature, a battery current, and a battery voltage of the secondary battery, a measurement value storing process of storing the battery temperature, the battery current, and the battery voltage that are measured, in chronological order, a capacity estimating process of estimating the current estimated charge capacity of the secondary battery, a conforming discharge period detecting process of detecting occurrence of a conforming discharge period in which a conforming discharge that conforms to a predetermined set of discharge conditions is performed, using the battery temperature, the battery current, and the battery voltage, a measured voltage drop amount acquiring process of obtaining a measured voltage drop amount that appears during the detected conforming discharge period, using the battery voltage, an estimated voltage drop amount acquiring process of obtaining an estimated voltage drop amount that is estimated to appear during the conforming discharge period, using the estimated charge capacity, a duration of the conforming discharge period, the battery temperature during the conforming discharge period, and the battery current flowing during the conforming discharge period, and a determining process of determining whether there is abnormal deterioration in the secondary battery, from the measured voltage drop amount and the estimated voltage drop amount.

As described above, when the secondary battery is experiencing abnormal deterioration, such as significant reduction of the salt concentration in the electrolyte, this has little effect on the behavior of the secondary battery when it is recharged. However, when the secondary battery is discharged, a large reduction of the battery voltage relative to that before the discharge or immediately after the discharge appears. Thus, according to the method of determining the deterioration status of the secondary battery, the measured voltage drop amount that appeared during the conforming discharge period in which the conforming discharge that satisfies predetermined discharge conditions is performed is obtained. In addition, the estimated voltage drop amount in the case of normal deterioration is estimated using the current estimated charge capacity, and it is determined whether there is an abnormal voltage drop in the secondary battery from the measured voltage drop amount and the estimated voltage drop amount. Therefore, it is possible to appropriately determine whether abnormal deterioration that causes the abnormal voltage drop has occurred in the secondary battery.

(6) In the method for determining the deterioration status of the secondary battery described in (5) above, the estimated voltage drop amount acquiring process may comprise obtaining a linear function equation in advance using, as a variable, an average C-rate that is an average of a C-rate obtained by dividing the battery current by the estimated charge capacity over the conforming discharge period, and obtaining the estimated voltage drop amount using the linear function equation.

According to the deterioration status determining method, in the estimated voltage drop amount acquiring process, the estimated voltage drop amount is obtained using the predetermined linear function equation using the average C-rate of the battery current flowing during the conforming discharge period as a variable; therefore, it is possible to easily determine whether abnormal deterioration has occurred in the secondary battery, based on the difference between the estimated voltage drop amount and the measured voltage drop amount.

(7) In the method for determining the deterioration status of the secondary battery described in (5) or (6) above, the determining process may include a deviation state acquiring process of obtaining an index of a deviation state between the estimated voltage drop amount and the measured voltage drop amount, and a deviation state determining process of determining whether there is the abnormal deterioration based on the obtained index of the deviation state.

According to the deterioration status determining method, the determining process includes the deviation state acquiring process of obtaining the deviation state index, and the deviation state determining process of determining whether there is abnormal deterioration based on the deviation state index. As the presence or absence of abnormal deterioration is determined using the deviation state index, the determining process is easy.

(8) In the method for determining the deterioration status of the secondary battery described in any one of (5) to (7) above, the conforming discharge performed during the conforming discharge period detected in the conforming discharge period detecting process may be a high-current conforming discharge in which the battery current of 75 A or more on average flows.

According to this method, in the high-current conforming discharge performed during the conforming discharge period detected in the conforming discharge period detecting process, a large battery current of 75 A or more on average is passed through the battery during the conforming discharge period. Therefore, according to this method, the “voltage drop amount ΔV” that appears when the secondary battery is experiencing abnormal deterioration is likely to be larger than the “voltage drop amount ΔV” in the case of normal deterioration, making it easier to determine whether there is abnormal deterioration.

### BRIEF DESCRIPTION OF THE DRAWINGS

FIG. 1 is a vertical cross-sectional view of a battery according to one embodiment;

FIG. 2 is a graph indicating the relationship between the average C-rate and current value of discharge current that is passed through the battery according to the embodiment, and the estimated voltage drop amount and the measured voltage drop amount;

FIG. 3 is a block diagram showing the configuration of a deterioration status determination system for determining the deterioration status of batteries that make up a battery pack, according to the embodiment;

FIG. 4 is an explanatory view showing a connection state of each of the batteries that make up the battery pack, and a measuring unit that measures the battery temperature, battery voltage and battery current of each battery, in the deterioration status determination system, according to the embodiment;

FIG. 5 is a graph indicating changes in the battery temperature, C-rate or battery current, and battery voltage with time when the battery is discharged, according to the embodiment;

FIG. 6 is a flowchart showing steps of a measurement process, as part of the procedure for determining the deterioration status of the battery, according to the embodiment;

FIG. 7 is a flowchart showing the first half of steps of an abnormal deterioration detection process, as part of the procedure for determining the deterioration status of the battery, according to the embodiment; and

FIG. 8 is a flowchart showing the second half of the steps of the abnormal deterioration detection process, as part of the procedure for determining the deterioration status of the battery, according to the embodiment.

### DETAILED DESCRIPTION OF THE EXEMPLARY EMBODIMENTS

### Embodiment

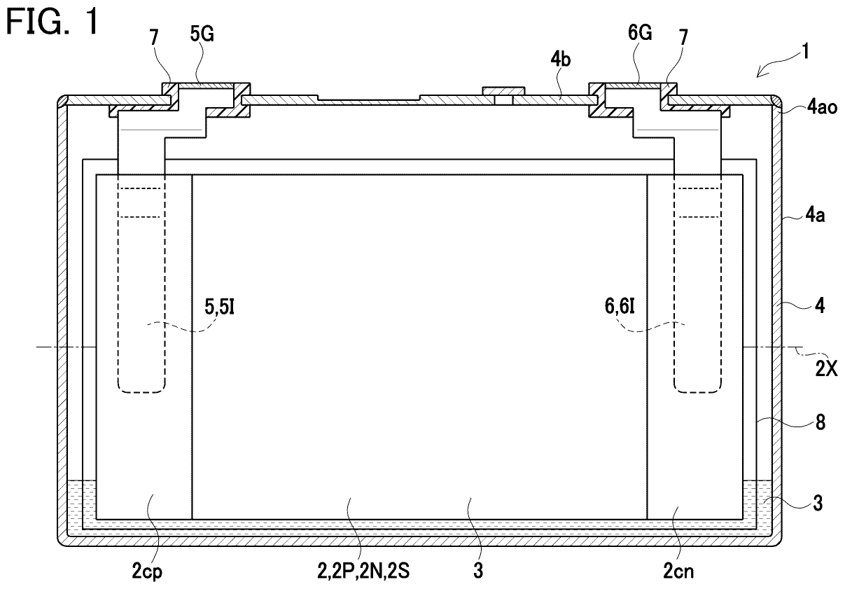

A battery 1 (one example of the secondary battery of the disclosure), which is a lithium-ion secondary battery, according to one embodiment will be described with reference to FIG. 1. The battery 1 is a rectangular sealed lithium-ion secondary battery, and is installed in various types of equipment including vehicles, such as hybrid electric vehicles (HEVs), plug-in hybrid electric vehicles (PHEVs), and electric vehicles (BEVs), and drones.

The battery 1 of this embodiment consists of a rectangular battery case 4, an electrode body 2 housed inside the battery case 4, and an electrolyte 3 with which the electrode body 2 housed in the battery case 4 is impregnated. The battery case 4 is made of metal (aluminum in this embodiment) and is shaped like a rectangular parallelepiped box. The battery case 4 has a case body 4a in the form of a rectangular tube with a bottom, and a lid 4b that is welded to an opening portion 4ao of the case body 4a to seal the opening portion 4ao. The electrode body 2 is covered with a rectangular bag-like insulating film 8 in the battery case 4. The above-mentioned electrolyte 3 is contained in the battery case 4, and the electrode body 2 is impregnated with part of the electrolyte 3 while the other part of it accumulates on the bottom of the battery case 4. A positive terminal 5 and a negative terminal 6 are fixedly mounted on the lid 4b of the battery case 4 via insulating members 7. The positive terminal 5 is connected to a positive current collector 2cp located in one end portion (the left end portion in FIG. 1) of the electrode body 2, and the negative terminal 6 is connected to a negative current collector 2cn located in the other end portion (the right end portion in FIG. 1) of the electrode body 2.

The electrode body 2 housed in the battery case 4 is a so-called flat wound-type electrode body that is known, and is formed by winding a strip-shaped positive electrode plate 2P and a strip-shaped negative electrode plate 2N together with a pair of strip-shaped separators 2S, and pressing the wound body in the direction perpendicular to the paper in FIG. 1 to make it flat. The electrode body 2 is housed in the battery case 4 with the winding axis 2X extending in the horizontal direction.

The strip-shaped positive electrode plate 2P as part of the electrode body 2 is made up of a positive electrode current collector foil made of an aluminum foil and positive electrode active material layers laminated on both surfaces of the positive electrode current collector foil. The positive electrode active material layer is made up of positive electrode active material particles, conductive particles, and a binder. In this embodiment, lithium transition metal composite oxide particles, such as lithium nickel cobalt manganese composite oxide particles, are used as the positive electrode active material particles. An end portion of the strip-shaped positive electrode plate 2P on one side (the left side in FIG. 1) in the width direction is the above-mentioned positive current collector 2cp in which the positive electrode current collector foil that is exposed folds into a spiral shape.

On the other hand, the strip-shaped negative electrode plate 2N as part of the electrode body 2 is made up of a negative electrode current collector foil made of a copper foil and negative electrode active material layers laminated on both surfaces of the negative electrode current collector foil. The negative electrode active material layer is made up of negative electrode active material particles and a binder. In this embodiment, graphite particles are used as the negative electrode active material particles. An end portion of the strip-shaped negative electrode plate 2N on the other side (the right side in FIG. 1) in the width direction is the above-mentioned negative current collector 2cn in which the negative electrode current collector foil that is exposed folds into a spiral shape.

The positive terminal 5 is formed by bending an aluminum plate. A positive electrode internal connecting portion 51 that is one end portion of the positive terminal 5 is welded to the positive current collector 2cp of the positive electrode plate 2P that constitutes the electrode body 2. On the other hand, the other end portion of the positive terminal 5 is pulled out of the battery case 4 to form a positive electrode external terminal portion 5G.

The negative terminal 6 is formed by bending a copper plate. A negative electrode internal connecting portion 61 that is one end portion of the negative terminal 6 is welded to the negative current collector 2cn of the negative electrode plate 2N that constitutes the electrode body 2. On the other hand, the other end portion of the negative terminal 6 is pulled out of the battery case 4 to form a negative electrode external terminal portion 6G.

The electrolyte 3 is a non-aqueous electrolyte that has an organic solvent and a lithium salt containing fluorine as a supporting salt. In this embodiment, an organic solvent that is a mixture of ethylene carbonate, ethyl methyl carbonate, and dimethyl carbonate is used as the above organic solvent. LiPF₆ is used as the lithium salt containing fluorine. The salt concentration of the lithium salt in the electrolyte 3 when poured into the battery case 4 is 1.1 M.

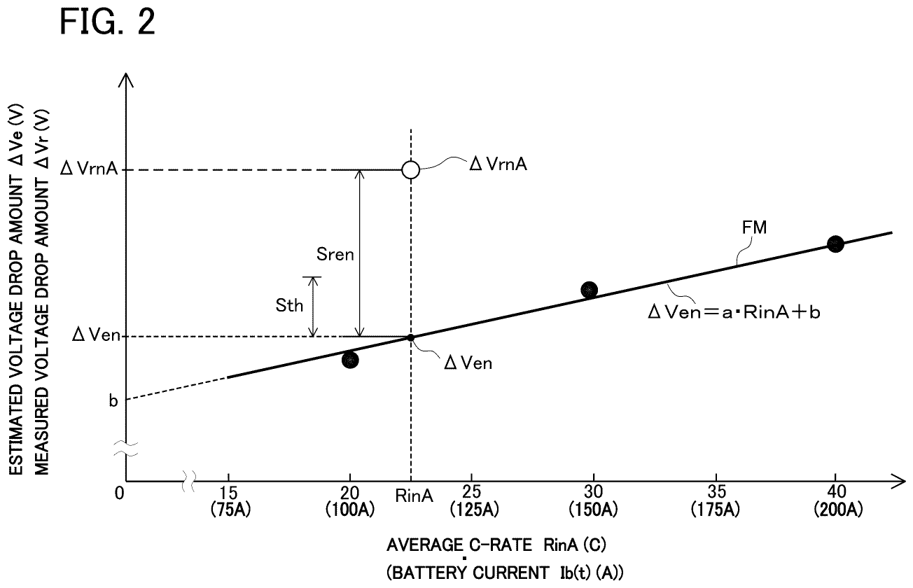

The characteristics of the battery 1 deteriorate as the battery 1 is repeatedly discharged and charged during use. Therefore, the battery capacity (charge capacity and discharge capacity) of the battery 1 gradually decreases. However, when the battery 1 is normally deteriorated, that is, the deterioration of the battery 1 is normally occurring deterioration, which will be called “normal deterioration”, and when the battery 1 is discharged at the same C-rate from the same battery voltage under the same battery temperature, a voltage drop of substantially the same magnitude, relative to the battery voltage at the start of the discharge, appears during the discharge, regardless of the degree of progression of deterioration. As the discharge current and its C-rate increase, the amount of voltage drop increases. Specifically, in the graph where the horizontal axis is the C-rate of the discharge current and the vertical axis is the voltage drop amount, when the battery 1 is normally deteriorated, the relationship between the C-rate of the discharge and the amount of voltage drop that occurs during discharge is generally represented by the graph rising to the right, as indicated by the solid line in FIG. 2, for example. Furthermore, this relationship remains substantially the same regardless of the degree of progression of normal deterioration of the battery 1. That is, it has been found that, where the C-rate is used as a variable, and the battery 1 is normally deteriorated, the amount of voltage drop occurring during discharge generally follows the same linear function equation FM regardless of the degree of progression of the normal deterioration. FIG. 2 shows the characteristics of the battery 1 of a high-output type with a charge capacity of 5Ah. As indicated in parentheses along the horizontal axis, a battery current of 100 A during discharge, for example, corresponds to 20 C in C-rate, and a battery current of 150 A corresponds to 30 C in C-rate. Also, the magnitude of the battery current flowing through the battery 1 installed in a vehicle during discharge is often not constant. Therefore, in FIG. 2, the average C-rate, which is the average of the C-rates over the discharge period, is used instead of the C-rate, as described above.

On the other hand, it has been found that, when the salt concentration in the electrolyte 3 in the electrode body 2 is reduced due to driving of the battery 1 at high temperatures, for example, the battery 1 is abnormally deteriorated, that is, the battery 1 is brought into a state of abnormal deterioration that is different from the normal deterioration. In addition, it has been found that, when the battery 1 that is abnormally deteriorated is discharged at the same C-rate from the same battery voltage under the same battery temperature, as described above, a voltage drop that is larger than that of the battery 1 that is normally deteriorated, relative to the battery voltage immediately after the start of the discharge, occurs during the discharge. Specifically, it has been found that, as indicated by the white circle “o” in the graph of FIG. 2, the amount of voltage drop that occurs during discharge in the battery 1 that is abnormally deteriorated deviates upward from, i.e., is larger than, the graph of the linear function equation FM indicated by the solid line. In other words, it can be determined whether abnormal deterioration occurs in the battery 1, depending on whether the amount of voltage drop appearing during discharge is larger than the graph of the linear function equation FM indicated by the solid line. Although it is not shown in the graph of FIG. 2, in the battery that is abnormally deteriorated, as the C-rate of discharge increases and as the abnormal deterioration progresses more, the deviation from the graph of the linear function equation FM increases. This is considered to be because the voltage drop due to the diffusion resistance that appears around the positive electrode during discharge because of abnormal deterioration becomes greater.

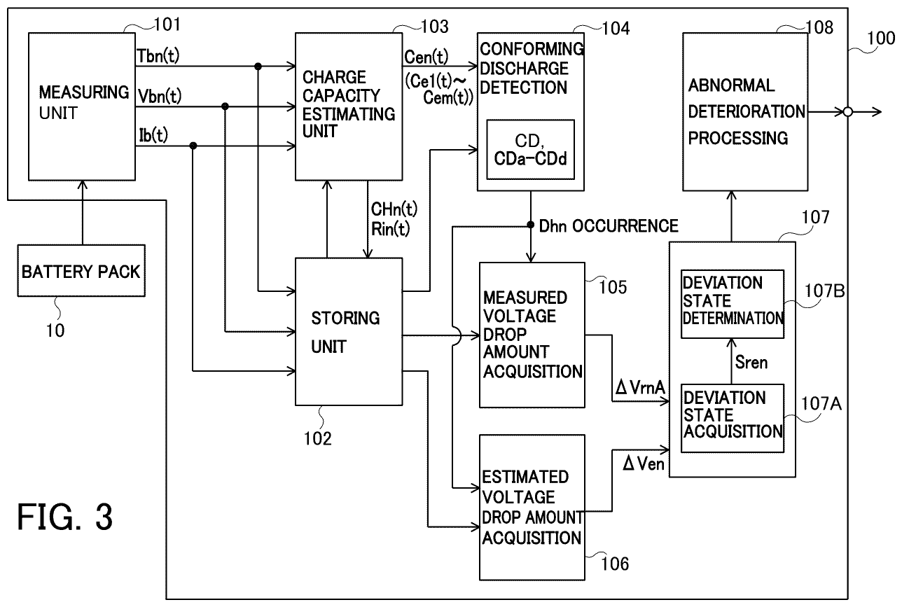

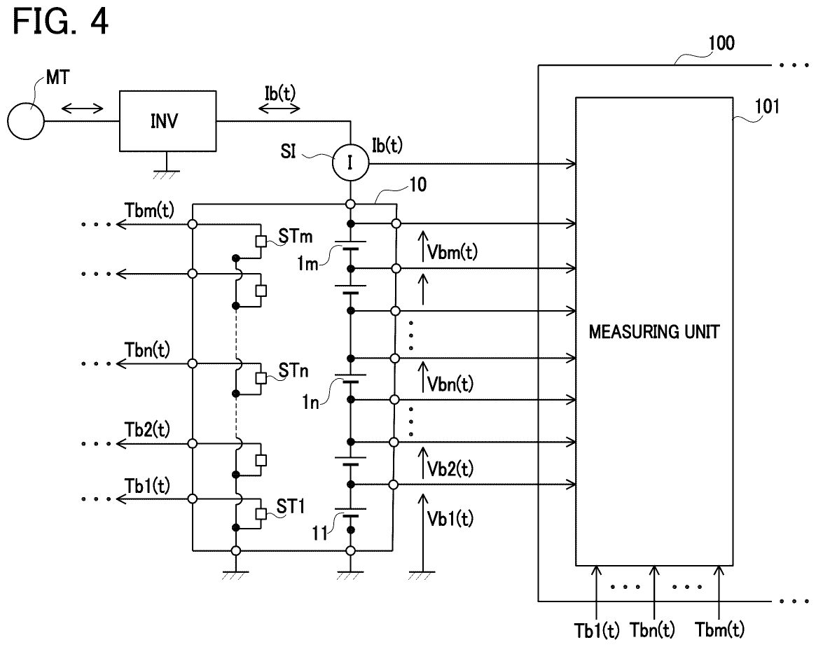

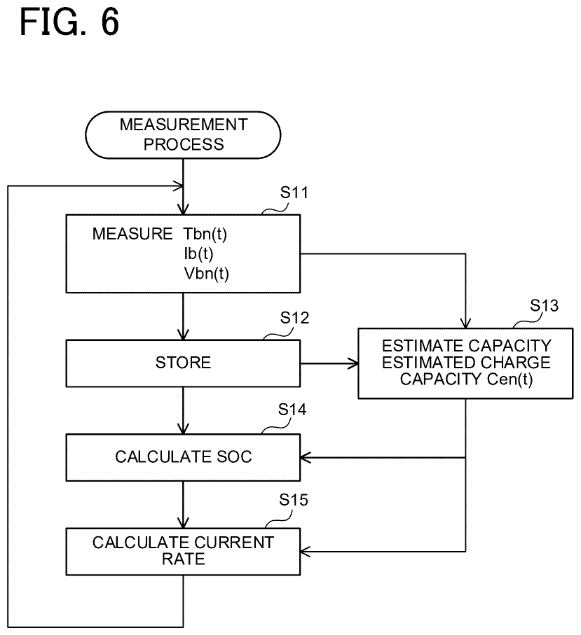

Thus, in the following, a deterioration status determination system 100 (see FIG. 3 to FIG. 5) and a deterioration status determining method (see FIG. 6 to FIG. 8) for determining whether abnormal deterioration occurs in the battery 1, according to the embodiment, will be described. In this embodiment, m (e.g., m=24) pieces of batteries 1 (denoted as battery 11 to battery 1m) are connected in series and used as a battery pack 10, as shown in FIG. 4. The battery pack 10 is connected to an inverter INV and used for driving a motor MT installed in an electric vehicle (not shown), for example, via the inverter INV. It is also possible to use the motor MT as a generator and regeneratively charge each battery 1 of the battery pack 10 via the inverter INV. The deterioration status determination system 100 is configured as part of a control system of the battery pack 10, which is made up of a CPU, memory, etc. that are not shown in the drawings.

In the following description, for the sake of simplicity, symbol “n” is used to denote the n-th battery 1n as counted from the low potential side, out of the m pieces of batteries 11 to 1m, so that the n-th battery 1n represents the batteries 11 to 1m, and description about the battery 1n may replace description about the batteries 11 to 1m.

The m pieces of batteries 11 to 1m that make up the battery pack 10 are respectively connected to a measuring unit 101, and the battery voltages Vb1(t) to Vbm(t) can be detected at predetermined time intervals (e.g., every 100 msec). Temperature sensors ST1 to STm are respectively mounted on the batteries 11 to 1m. The temperature sensors ST1 to STm are also respectively connected to the measuring unit 101, and the battery temperatures Tb1(t) to Tbm(t) can be detected at predetermined time intervals. Furthermore, a current sensor SI connected in series to the battery pack 10 and the inverter INV is provided between the battery pack 10 and the inverter INV, and the battery current Ib(t) that flows in common through each of the batteries 11 to 1m due to charging and discharging of the batteries 11 to 1m is detected at predetermined time intervals and input to the measuring unit 101. In this specification, the battery current for discharge is denoted as a current with a plus sign (+), and the battery current for charge is denoted as a current with a minus sign (−).

As described above, the measuring unit 101 acquires the battery temperature Tbn(t), battery current Ib(t), and battery voltage Vbn(t) of the battery 1n of the battery pack 10 at predetermined time intervals, and stores them in a storing unit 102 in chronological order. In parallel with the data storage in the storing unit 102, a capacity estimating unit 103 estimates the estimated charge capacity Cen(t) of the battery 1n, using the current and past data acquired by the measuring unit 101 and stored in the storing unit 102.

The capacity estimating unit 103 may estimate the estimated charge capacity Cen(t) of the battery 1n by an appropriately selected method. For example, the capacity estimating unit 103 may estimate the estimated charge capacity Cen(t), using the transition of the battery temperature Tbn(t) to which the battery 1n has been exposed since the battery 1n was installed in a vehicle (not shown) and energized. This is because the deterioration of the battery 1n tends to progress when the battery temperature Tbn(t) is high. It is, however, to be noted that, even if the same batteries 11 to 1m are housed in a single battery pack 10, the battery temperatures Tb1(t) to Tbm(t) may differ due to differences in the ease of heat input from the outside and heat dissipation depending on the location. Therefore, the estimated charge capacities Ce1(t) to Cem(t) of the respective batteries 11 to 1m may differ among the batteries. Thus, in this embodiment, the estimated charge capacities Cen1(t) to Cem(t) are respectively estimated for the individual batteries 11 to 1m. Since it is considered that the estimated charge capacity Cen(t) of the battery 1n gradually decreases due to deterioration but does not change in a short period of time, the estimated charge capacity Cen(t) may be regarded as being constant over a conforming discharge period Dhn that will be described below, for example. The capacity estimating unit 103 estimates the estimated charge capacity Cen(t) of the battery 1n, because the magnitude of the charge capacity is not likely to be affected by the abnormal deterioration described above, and is not likely to differ from that in the case of normal deterioration.

In addition, the capacity estimating unit 103 uses the past and current data measured by the measuring unit 101 and the estimated charge capacity Cen(t) to obtain the current SOC (State of Charge) CHn(t) of the battery 1n and the C-rate Rin(t) of the flowing battery current Ib(t), and stores them in the storing unit 102. The C-rate Rin(t) is calculated by dividing the battery current Ib(t) flowing through the battery 1n by the estimated charge capacity Cen(t) (Rin(t)=Ib(t)/Cen(t)).

A conforming discharge period detecting unit 104 detects the occurrence of the conforming discharge period Dhn in which conforming discharge that conforms to a predetermined set of discharge conditions CD is performed, using the present and past battery temperatures Tbn(t), battery currents Ib(t), and battery voltages Vbn(t) of the battery 1n that have been measured and stored. Specifically, the conforming discharge period detecting unit 104 detects the time of beginning (start time ts) and the time of termination (end time te) of the conforming discharge period Dhn. More specifically, in this embodiment, when the battery 1n performs a conforming discharge that satisfies the following four discharge sub-conditions CDa to CDd as the set of discharge conditions CD in a test period DTn, the conforming discharge period detecting unit 104 sets the test period DTn as the conforming discharge period Dhn and detects the occurrence of the conforming discharge period Dhn.
CDa: The SOC CHn(ts) of the battery 1n at the start time ts of the test period DTn is within a specified range (e.g., CHn(ts)=60±5% in this embodiment).
CDb: The average battery temperature TbnA of the battery temperatures Tbn(t) measured during the test period DTn including the start time ts is within a specified temperature range (e.g., TbnA=25±5° C. in this embodiment).
CDc: The average C-rate RinA, which is the average value of the C-rates Rin(t) of the battery currents Ib(t) discharged from the battery 1n during the test period DTn including the start time ts, is within a specified C-rate range (e.g., RinA=+30±10 C in this embodiment).
CDd: The length Ln of the test period DTn in which the above-mentioned discharge sub-conditions CDa to CDc are satisfied has reached a specified duration DLn (e.g., Ln≥10 sec=DLn in this embodiment).
The point in time at which the length Ln of the test period DTn reached the duration DLn is set as the end time te.

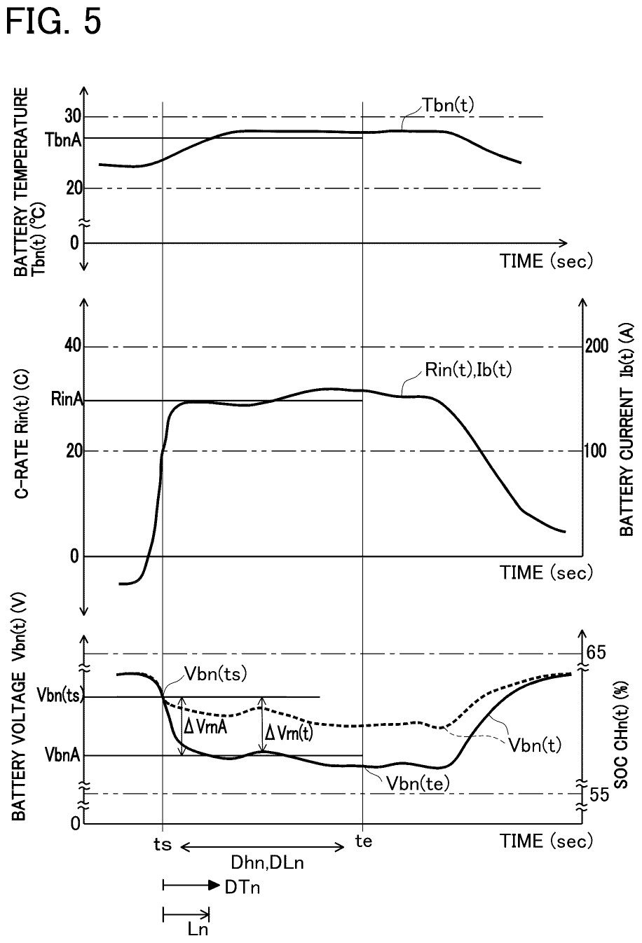

Specifically, as shown in FIG. 5, for example, the time t at which the SOC CHn(t) of the battery 1n is between 55% and 65%, the battery temperature Tbn(t) is between 20° C. and 30° C., and the magnitude of the battery current Ib(t) during discharge has increased until the C-rate Rin(t) of discharge becomes equal to +20 C or more is set as the start time ts, and measurement of the test period DTn is started. From this point on, the test period DTn continues when the average battery temperature TbnA during the test period DTn concerned is between 20° C. and 30° C. and the average C-rate RinA of discharge during the test period DTn is within the range of +20 C to +40C. On the other hand, when the average battery temperature TbnA falls outside the range of 20° C. to 30° C., or when the average C-rate RinA falls outside the range of +20 C to +40 C, the test period DTn is terminated. Then, the time t at which the test period DTn is continued and the length Ln becomes equal to 10 seconds is set as the end time te, at which the test period DTn is terminated. Furthermore, the test period DTn is set as the conforming discharge period Dhn, and the occurrence of the conforming discharge period Dhn of which the time of beginning is the start time ts and the time of termination is the end time te and during which the conforming discharge that conforms to the set of discharge conditions CD is performed is detected.

Examples of vehicle operating conditions that satisfy the above-mentioned set of discharge conditions CD (discharge sub-conditions CDa to CDd) include driving up a slope or hill and accelerating rapidly to enter a highway from an interchange, etc. On the other hand, the set of discharge conditions CD may be changed in order to increase the opportunities to determine whether there is abnormal deterioration during vehicle operation. For example, the range of the average C-rate RinA specified in the discharge sub-condition CDc may be changed to a lower range, such as 5 C to 15 C, or even lower, such as 3 C to 8 C. In addition, the contents of other discharge sub-conditions CDa, CDb, CDd may also be changed as appropriate, for example, the length of the duration DLn may be increased in accordance with the change in the range of the average C-rate RinA.

Meanwhile, a measured voltage drop acquiring unit 105 obtains the measured voltage drop amount ΔVrnA that appeared during the detected conforming discharge period Dhn. Specifically, the difference between the battery voltage Vbn (ts) at the start time ts as a reference value and the battery voltage Vbn(t) at each time t is defined as the voltage drop amount ΔVrn(t) (ΔVrt(t)=Vbn(ts)−Vbn(t)). Then, the measured voltage drop acquiring unit 105 obtains the average value of the voltage drop amount ΔVrn(t) over the entire conforming discharge period Dhn from the start time ts to the end time te, using the voltage drop amount ΔVrn(t) obtained at each time t, and sets the obtained average value as the measured voltage drop amount ΔVrnA. The measured voltage drop amount ΔVrnA corresponds to the difference between the battery voltage Vbn(ts) at the start time ts and the average battery voltage VbnA as the average value of the battery voltage Vbn(t) during the conforming discharge period Dhn.

An estimated voltage drop acquiring unit 106 obtains the estimated voltage drop amount ΔVen that is estimated to appear during the conforming discharge period Dhn when the detected battery 1n is not abnormally deteriorated, using the estimated charge capacity Cen(t), the duration DLn (DLn=10 sec in this embodiment) of the conforming discharge period Dhn, the battery temperature Tbn(t) during the conforming discharge period Dhn, and the battery current Ib(t) that flowed during the conforming discharge period Dhn. Specifically, in this embodiment, the estimated voltage drop acquiring unit 106 obtains the estimated voltage drop amount ΔVen, using the estimated charge capacity Cen(t) estimated by the capacity estimating unit 103, the average battery temperature TbnA of the battery temperature Tbn(t) during the conforming discharge period Dhn, and the average C-rate RinA obtained from the battery current Ib(t) of discharge that flowed during the conforming discharge period Dhn. More specifically, the estimated voltage drop amount ΔVen corresponding to the average C-rate RinA is obtained, using the graph indicated by the solid line in FIG. 2 and obtained in advance.

Alternatively, the estimated voltage drop amount ΔVen corresponding to the average C-rate RinA may also be calculated, using the linear function equation FM (ΔVen=a·RinA+b) indicated by the graph with the average C-rate RinA as a variable, instead of the graph indicated by the solid line in FIG. 2. By using the linear function equation FM, it is possible to easily determine whether the battery 1n is undergoing abnormal deterioration. The coefficient “a” in the linear function equation FM corresponds to the magnitude of a resistance component, such as diffusion resistance, that appears in the battery 1n.

The graph indicated by the solid line in FIG. 2 and the linear function equation FM may be obtained in advance as follows. While the battery 1 at the beginning of use or the battery 1 that is normally deteriorated is held at a specific battery temperature (e.g., 25° C.) with a specific SOC (e.g., SOC 60%), a discharge corresponding to each C-rate (e.g., +20 C, +30 C, +40 C) is performed for 10 seconds (corresponding to the duration DLn of the conforming discharge period Dhn). Then, the voltage drop amount as a difference between the battery voltage immediately after the start of the discharge (corresponding to the start time ts) as a reference value and the average value of the battery voltage that appears subsequently is obtained and plotted as indicated by black dots • in FIG. 2, for example, and the dots are connected to obtain the graph indicated by the solid line and the linear function equation FM.

In this connection, the graph or the linear function equation may be obtained in the manner as described above, by performing discharge at different battery temperatures or over different durations. The graphs or the linear function equations thus obtained may be collectively stored in the form of a lookup table.

A determining unit 107 determines whether there is an abnormal voltage drop of the battery 1n, from the measured voltage drop amount ΔVrnA obtained by the measured voltage drop acquiring unit 105 and the estimated voltage drop amount ΔVen obtained by the estimated voltage drop acquiring unit 106. Specifically, initially, a deviation state acquiring unit 107A obtains a deviation state index indicating a deviation between the estimated voltage drop amount ΔVen and the measured voltage drop amount ΔVrnA. Specifically, in this embodiment, the deviation amount Sren is obtained. The deviation amount Sren is a difference (Sren=ΔVrnA−ΔVen) between the measured voltage drop amount ΔVrnA and the estimated voltage drop amount ΔVen.

As the deviation state index, indexes indicating the degree of deviation of the measured voltage drop amount ΔVrnA from the estimated voltage drop amount ΔVen, other than the above-mentioned deviation amount Sren, may be used. For example, the deviation ratio (=ΔVrnA/ΔVen) obtained by dividing the measured voltage drop amount ΔVrnA by the estimated voltage drop amount ΔVen, the deviation rate ((ΔVrnA-ΔVen)/ΔVen) obtained by dividing the deviation amount Sren by the estimated voltage drop amount ΔVen, etc. may be used.

Subsequently, a deviation state determining unit 107B determines whether there is abnormal deterioration, based on the obtained deviation state index (the deviation amount Sren in this embodiment). That is, when the deviation state determining unit 107B can determine that the measured voltage drop amount ΔVrnA largely deviates from the estimated voltage drop amount ΔVen, it determines that abnormal deterioration has occurred in the battery 1n. Specifically, when the deviation state index exceeds a threshold value set in advance, the deviation state determining unit 107B determines that abnormal deterioration has occurred. In this embodiment, the determination is made based on whether the deviation amount Sren is equal to or larger than a threshold deviation amount Sth set in advance (Sren≥Sth).

When the deviation amount Sren is smaller than the threshold deviation amount Sth (Sren<Sth), it is determined that no abnormal deterioration has occurred in the battery 1n, and the determining unit 107 stops processing and returns to the conforming discharge period detecting unit 104 to wait for the occurrence of the conforming discharge period Dhn.

On the other hand, when the deviation amount Sren is equal to or larger than the threshold deviation amount Sth (Sren≥Sth), it can be determined that the abnormal deterioration that causes the abnormal voltage drop has occurred in the battery 1n.

Of the conforming discharges that satisfy each of the discharge sub-conditions CDa to CDd that make up the set of discharge condition CD, the discharge with a battery current Ib(t) of 75A or more on average (corresponding to a C-rate of +15 C or more in this embodiment) is defined as high-current conforming discharge. As described above, in this embodiment, the discharge sub-condition CDc specifies that the range of the average C-rate RinA is +30±10 C; therefore, the discharge that satisfies the above set of discharge conditions CD corresponds to the high-current conforming discharge. In the case of high-current conforming discharge, a large battery current of 75 A or more on average is passed through the battery 1 during the conforming discharge period; therefore, the “measured voltage drop amount ΔVrnA” obtained when the battery 1 is abnormally deteriorated is likely to be larger than the “estimated voltage drop amount ΔVen” corresponding to the case of normal deterioration, and the presence or absence of abnormal deterioration can be easily determined by using the above-mentioned deviation amount Sren, or the like.

Subsequently, an abnormal deterioration processing unit 108 performs predetermined processing or measures against abnormal deterioration. For example, the measures include correction of the SOC, the remaining battery level, and the vehicle's possible driving distance in the reducing direction. In the case of abnormal deterioration, even if the display shows that the remaining battery level is high and the possible driving distance is still sufficient, the battery voltage Vbn(t) of the battery 1n may be significantly reduced when the discharge is performed at a high C-rate, such as when the vehicle is rapidly accelerated or climbs a steep hill, and the battery voltage Vbn(t) may fall below the lower limit of the usable voltage of the battery 1n, causing the battery to be considered empty and making it practically difficult to drive the vehicle. Examples of the measures against abnormal deterioration also include displaying a warning light for the vehicle driver, notifying a service center of the occurrence of abnormal deterioration via communication, changing the operating mode of the vehicle to an operating mode for avoiding high C-rate discharge or an operating mode for reducing the air conditioning power consumption.

Thus, the deterioration status determination system 100 can properly determine whether deterioration that causes an abnormal voltage drop has occurred in the battery 1n.

In this embodiment, the deviation state acquiring unit 107A and deviation state determining unit 107B of the determining unit 107 calculate the deviation state index (the deviation amount Sren) and determine whether there is abnormal deterioration by using the index. Thus, the determining process is easy.

The deviation state determining unit 107B of this embodiment determines whether there is abnormal deterioration, using the deviation amount Sren. However, the deviation state determining unit 107B may determine the degree of abnormal deterioration in addition to the presence or absence of abnormal deterioration. That is, two or more types of the magnitude of the threshold deviation amount Sth with which the deviation amount Sren is compared may be set, and the level of abnormal deterioration may be selected from two or more levels, e.g., Level 1, Level 2, and Level 3, for determination of the degree of abnormal deterioration.

The procedure for determining the deterioration status of the battery 1n according to this embodiment will be described with reference to the flowcharts of FIG. 6 to FIG. 8. First, steps of the measurement process shown in FIG. 6 will be described. The measurement process steps mainly correspond to processing performed by the measuring unit 101, storing unit 102, and capacity estimating unit 103 of the deterioration status determination system 100 described above.

First, in a measuring step S11, the measuring unit 101 measures the battery temperature Tbn(t) of the battery 1n at predetermined time intervals, using a temperature sensor STn mounted on the battery 1n. The measuring unit 101 also measures the battery voltage Vbn(t). Furthermore, the measuring unit 101 measures the battery current Ib(t) of charge/discharge flowing through the battery 1n, using the current sensor SI. In this manner, the battery temperature Tbn(t), battery voltage Vbn(t), and battery current Ib(t) of the battery 1n are obtained at predetermined time intervals. In a storing step S12, the measurement values are stored in chronological order in the storing unit 102.

In parallel with the storing step S12, a capacity estimating step S13 is executed to obtain the estimated charge capacity Cen(t) of the battery 1n, using the obtained current battery temperature Tbn(t), battery voltage Vbn(t), and battery current Ib(t) of the battery 1n and the stored past data of each measurement value.

In a SOC calculating step S14, the SOC CHn(t) of the battery 1n is obtained. Furthermore, in a C-rate calculating step S15, the battery current Ib(t) flowing through the battery 1n is converted into the C-rate Rin(t). Specifically, the C-rate Rin(t) is obtained by dividing the battery current Ib(t) by the estimated charge capacity Cen(t) of the battery 1n. In this embodiment, these steps S11 to S15 are repeatedly executed at predetermined time intervals to measure the battery temperature Tbn(t), battery voltage Vbn(t), and battery current Ib(t) of the battery 1n, and obtain the estimated charge capacity Cen(t) and the C-rate Rin(t).

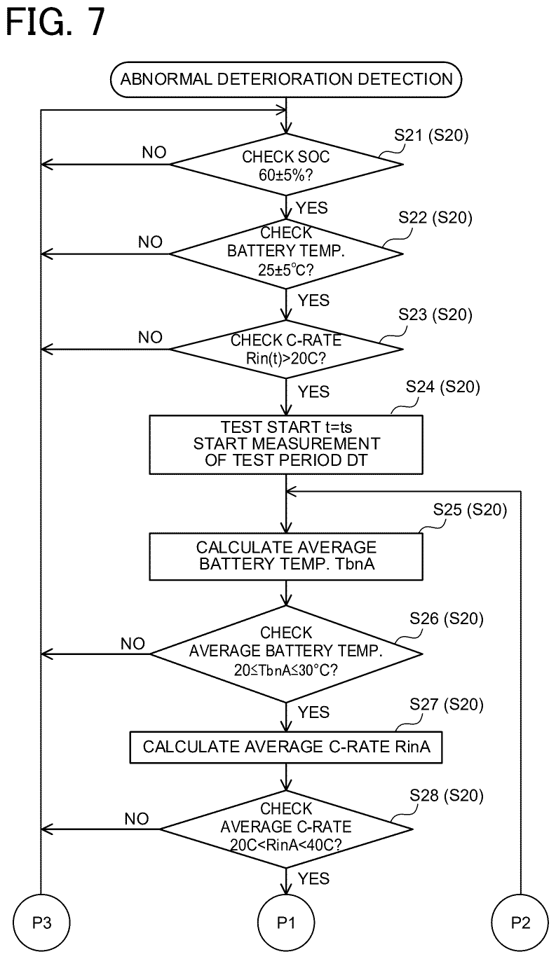

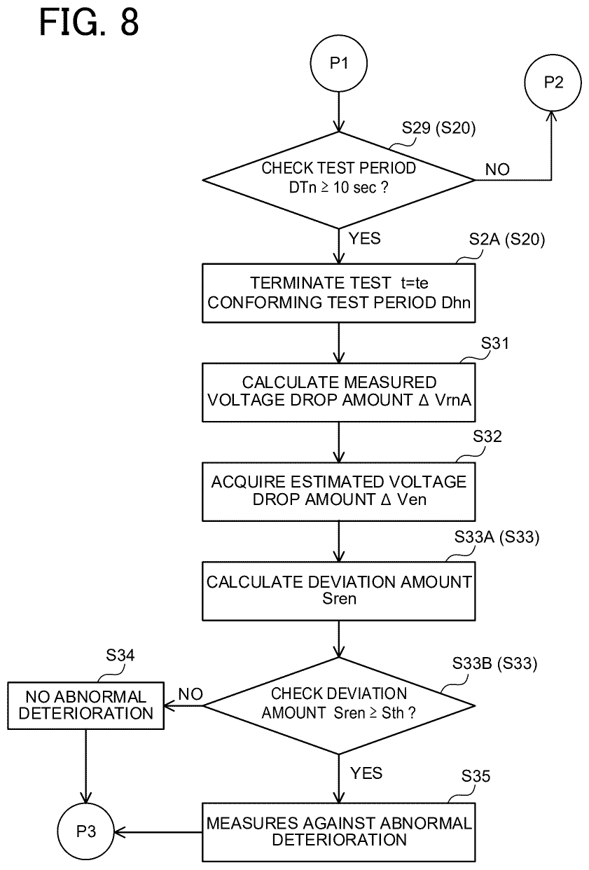

Next, steps of the abnormal deterioration detection process will be described with reference to the flowcharts of FIG. 7 and FIG. 8. The abnormal deterioration detection process is performed at predetermined time intervals, separately from the measurement process described above. Step S21 to step S2A that will be described below make up a conforming discharge period detecting step S20 of detecting the occurrence of the conforming discharge period Dhn in which a conforming discharge that conforms to the predetermined set of discharge conditions CD is performed.

First, in a SOC checking step S21, which corresponds to the discharge sub-condition CDa, it is determined whether the current SOC CH(t) of the battery 1n obtained in the SOC calculating step S14 is within the specified range (CH(t)=60±5% in this embodiment). When NO is obtained, that is, when the SOC CH(t) is outside the specified range, the control flow returns to the SOC checking step S21. On the other hand, when YES is obtained, that is, when the SOC CH(t) is within the specified range, the control flow proceeds to a subsequent battery temperature checking step S22.

In the battery temperature checking step S22, it is determined whether the current battery temperature Tbn(t) of the battery 1n obtained in the measuring step S11 is within the specified range (Tbn(t)=25±5° C. in this embodiment). When NO is obtained, that is, when the battery temperature Tbn(t) is outside the specified range, the control flow returns to the SOC checking step S21. On the other hand, when YES is obtained, that is, when the battery temperature Tbn(t) is within the specified range, the control flow proceeds to a subsequent discharge rate checking step S23.

In the discharge rate checking step S23, it is determined whether the current C-rate Rin(t) of the battery 1n obtained in the C-rate calculating step S15 is within the specified discharge C-rate range (Rin(t)=+30±10 C in this embodiment). When NO is obtained, that is, when the C-rate Rin(t) is outside the specified range, the control flow returns to the SOC checking step S21. On the other hand, when YES is obtained, that is, when the C-rate Rin(t) is within the specified range, the control flow proceeds to a subsequent test starting step S24.

In the test starting step S24, the current time t is stored as the start time ts, and measurement of the test period DTn is started. However, when measurement of the test period DTn has already been started, the test starting step S24 is skipped.

In a subsequent average battery temperature calculating step S25, the average battery temperature TbnA, which is the average value of the battery temperatures Tbn(t) during the test period DTn, is calculated using the battery temperature Tbn(t) obtained at each point in time during the test period DTn.

In a subsequent average battery temperature checking step S26, it is determined whether the obtained average battery temperature TbnA is within the specified temperature range (TbnA=20° C. to 30° C. in this embodiment). When NO is obtained, that is, when the average battery temperature TbnA is outside the temperature range, the test period DTn is terminated, and the control flow returns to the SOC checking step S21. This is because the battery temperature is too low or too high, and the occurrence of abnormal deterioration cannot be properly determined. On the other hand, when YES is obtained, that is, when the battery temperature is within the specified range, the control flow proceeds to a subsequent average C-rate calculating step S27.

In the subsequent average C-rate calculating step S27, the average C-rate RinA, which is the average value of the C-rates Rin(t) during the test period DTn, is calculated using the C-rate Rin(t) obtained at each point in time during the test period DTn.

In a subsequent average C-rate checking step S28, it is determined whether the obtained average C-rate RinA is within the specified discharge C-rate range (RinA=+30±10 C in this embodiment). When NO is obtained in this step, that is, when the average C-rate RinA is outside the specified range, the test period DTn is terminated, and the control flow returns to the SOC checking step S21. This is because the discharge in the specified C-rate range is not continued, and the occurrence of abnormal deterioration cannot be properly determined. On the other hand, when YES is obtained, that is, when the average C-rate RinA is within the specified range, the control flow proceeds to a subsequent test period checking step S29 via a connection point P1.

In the test period checking step S29, it is determined whether the length Ln of the test period DTn from the start time ts has reached the specified duration DLn (Ln≥10 sec=DLn in this embodiment). When NO is obtained, that is, when the specified duration DLn has not passed, the control flow returns to the average battery temperature calculating step S25 via a connection point P2 in order to continue the test period DTn. On the other hand, when YES is obtained, that is, when the specified duration DLn has passed, the control flow proceeds to a subsequent test ending step S2A.

In the test ending step S2A, the current time t is stored as the end time te, measurement of the test period DTn is stopped, the test period DTn is set as the conforming discharge period Dhn, and the occurrence of the conforming discharge period Dhn that starts at the start time ts and ends at the end time te is detected.

In a subsequent measured voltage drop amount acquiring step S31, the measured voltage drop amount ΔVrnA that appeared during the detected conforming discharge period Dhn is obtained. Specifically, the measured voltage drop amount ΔVrnA is obtained in the same manner as that in which the measured voltage drop acquiring unit 105 does.

In a subsequent estimated voltage drop amount acquiring step S32, the estimated charge capacity Cen(t), the duration DLn (DLn=10 sec in this embodiment) of the conforming discharge period Dhn, the battery temperature Tbn(t) during the conforming discharge period Dhn, and the battery current Ib(t) that flows during the conforming discharge period Dhn are used to obtain the estimated voltage drop amount ΔVen that is estimated to appear during the conforming discharge period Dhn when the detected battery 1n is not abnormally deteriorated. Specifically, in the same manner as that in which the estimated voltage drop acquiring unit 106 obtains the estimated voltage drop amount ΔVen, the estimated voltage drop amount ΔVen corresponding to the average C-rate RinA is obtained, using the graph indicated by the solid line in FIG. 2.

Instead of the graph indicated by the solid line in FIG. 2, the linear function equation FM (ΔVen=a·RinA+b) indicated by the graph and using the average C-rate RinA as a variable may be used to calculate the estimated voltage drop amount ΔVen corresponding to the average C-rate RinA. By using the linear function equation FM, it can be easily determined whether abnormal deterioration has occurred in the battery 1n.

In a subsequent determining step S33, it is determined whether there is an abnormal voltage drop in the battery 1n, from the measured voltage drop amount ΔVrnA obtained in the measured voltage drop amount acquiring step S31 and the estimated voltage drop amount ΔVen obtained in the estimated voltage drop amount acquiring step S32.

First, in a deviation state acquiring step S33A, as part of the determining step S33, the deviation state index indicating the deviation between the estimated voltage drop amount ΔVen and the measured voltage drop amount ΔVrnA, specifically, the deviation amount Sren as the difference between the measured voltage drop amount ΔVrnA and the estimated voltage drop amount ΔVen is obtained.

In a subsequent deviation state determining step S33B, it is determined whether there is abnormal deterioration, based on the deviation amount Sren as the deviation state index obtained in the deviation state acquiring step S33A. In this embodiment, it is determined whether the deviation amount Sren is equal to or larger than the threshold deviation amount Sth set in advance. When NO is obtained, that is, when the deviation amount Sren is smaller than the threshold deviation amount Sth (Sren<Sth), the control flow proceeds to a no-deterioration processing step S34. On the other hand, when YES is obtained, that is, when the deviation amount Sren is equal to or larger than the threshold deviation amount Sth (Sren≥Sth), the control flow proceeds to a subsequent abnormal deterioration processing step S35.

In the no-deterioration processing step S34, it is determined that there is no abnormal deterioration in the battery 1n, and the control flow returns to the SOC checking step S21 via a connection point P3 to wait for the occurrence of another conforming discharge period Dhn.

In the abnormal deterioration processing step S35, it is determined that abnormal deterioration has occurred in the battery 1n, and the processing similar to that of the abnormal deterioration processing unit 108, e.g., predetermined measures against abnormal deterioration, such as correction of the SOC, the remaining battery level, and the vehicle's possible driving distance in the reducing direction, is performed. Then, the control flow proceeds to the SOC checking step S21 via the connection point P3 to wait for the occurrence of another conforming discharge period Dhn.

Thus, according to the deterioration status determining method of this embodiment, it can be properly determined whether deterioration that causes an abnormal voltage drop has occurred in the battery 1n. Also, in this embodiment, the deviation state index (the deviation amount Sren) is calculated and used to determine the presence of abnormal deterioration in the deviation state acquiring step S33A and the deviation state determining step S33B of the determining step S33. Thus, the determining process is easy.

While the disclosure has been described in the light of the embodiment, it is to be understood that the disclosure is not limited to the embodiment, but may be applied by making changes as needed, without departing from the principle of the disclosure.

In the illustrated embodiment, the capacity estimating unit 103 estimates the estimated charge capacity Cen(t). However, the estimated charge capacity maintenance rate may be estimated, and the estimated charge capacity Cen(t) may be obtained using the estimated charge capacity maintenance rate obtained.

In the illustrated embodiment, the battery 1 of high-output type with a charge capacity of 5Ah, which is mainly used in hybrid electric vehicles, is used as the battery 1. However, the disclosure may also be applied to the case where batteries with a larger or smaller charge capacity (battery capacity) are used. The disclosure may also be applied to the case where batteries of high-capacity type, which are mainly used in plug-in hybrid electric vehicles and battery electric vehicles, are used. When a battery of high-capacity type is used, the range of the average C-rate RinA specified in the discharge sub-condition CDc is preferably set to, for example, the range of 0.5 C to 1.5 C, in view of the magnitude of discharge current passed through the battery in the case of rapid acceleration, for example.

### REFERENCE SIGNS LIST

1, 11, 1n, 1m Battery (Secondary battery)
2 Electrode body
3 Electrolyte
Ce1(t), Cen(t), Cem(t) Estimated charge capacity
Tb1(t), Tbn(t), Tbm(t) Battery temperature
TbnA Average battery temperature
Ib(t) Battery current
Ri1(t), Rin(t), Rim(t) C-rate
RinA Average C-rate
FM Linear function equation
Vb1(t), Vbn(t), Vbm(t) Battery voltage
VbnA Average battery voltage
ΔVrn(t) Voltage drop amount
ΔVrnA Measured voltage drop amount
ΔVen Estimated voltage drop amount
Sren Deviation amount
Sth Threshold deviation amount
Dhn Conforming discharge period
DLn Duration
100 Deterioration status determination system
101 Measuring unit
102 Storing unit
103 Capacity estimating unit
104 Conforming discharge period detecting unit
CD, CDa-CDd Discharge condition
105 Measured voltage drop acquiring unit
106 Estimated voltage drop acquiring unit
107 Determining unit
107A Deviation state acquiring unit
107B Deviation state determining unit
108 Abnormal deterioration processing unit
S11 Measuring step
S12 Measurement value storing step
S13 Capacity estimating step
S20 Conforming discharge period detecting step
S31 Measured voltage drop amount acquiring step
S32 Estimated voltage drop amount acquiring step
S33 Determining step
S33A Deviation state acquiring step
S33B Deviation state determining step
S35 Abnormal deterioration processing step

What is claimed is:

1. A system for determining a deterioration status of a secondary battery that contains an electrode body impregnated with an electrolyte, comprising:
a measuring unit that measures a battery temperature, a battery current, and a battery voltage of the secondary battery;
a storing unit that stores the battery temperature, the battery current, and the battery voltage that are measured, in chronological order;
a capacity estimating unit that estimates the current estimated charge capacity of the secondary battery;
a conforming discharge period detecting unit that detects occurrence of a conforming discharge period in which a conforming discharge that conforms to a predetermined set of discharge conditions is performed, using the battery temperature, the battery current, and the battery voltage;
a measured voltage drop acquiring unit that obtains a measured voltage drop amount that appears during the detected conforming discharge period, using the battery voltage;
an estimated voltage drop acquiring unit that obtains an estimated voltage drop amount that is estimated to appear during the conforming discharge period, using the estimated charge capacity, a duration of the conforming discharge period, the battery temperature during the conforming discharge period, and the battery current flowing during the conforming discharge period; and
a determining unit that determines whether there is abnormal deterioration in the secondary battery, from the measured voltage drop amount and the estimated voltage drop amount.

2. The system according to claim 1, wherein the estimated voltage drop acquiring unit obtains the estimated voltage drop amount, using a linear function equation that is obtained in advance using an average C-rate as a variable, the average C-rate being an average of a C-rate obtained by dividing the battery current by the estimated charge capacity over the conforming discharge period.

3. The system according to claim 1, wherein the determining unit includes:
a deviation state acquiring unit that obtains an index of a deviation state between the estimated voltage drop amount and the measured voltage drop amount; and
a deviation state determining unit that determines whether there is the abnormal deterioration based on the obtained index of the deviation state.

4. The system according to claim 2, wherein the determining unit includes:
a deviation state acquiring unit that obtains an index of a deviation state between the estimated voltage drop amount and the measured voltage drop amount; and
a deviation state determining unit that determines whether there is the abnormal deterioration based on the obtained index of the deviation state.

5. The system according to claim 1, wherein the conforming discharge performed during the conforming discharge period detected by the conforming discharge period detecting unit is a high-current conforming discharge in which the battery current of 75 A or more on average flows.

6. The system according to claim 2, wherein the conforming discharge performed during the conforming discharge period detected by the conforming discharge period detecting unit is a high-current conforming discharge in which the battery current of 75 A or more on average flows.

7. The system according to claim 3, wherein the conforming discharge performed during the conforming discharge period detected by the conforming discharge period detecting unit is a high-current conforming discharge in which the battery current of 75 A or more on average flows.

8. The system according to claim 4, wherein the conforming discharge performed during the conforming discharge period detected by the conforming discharge period detecting unit is a high-current conforming discharge in which the battery current of 75 A or more on average flows.

9. A method for determining a deterioration status of a secondary battery that contains an electrode body impregnated with an electrolyte, comprising:
measuring a battery temperature, a battery current, and a battery voltage of the secondary battery;
storing the battery temperature, the battery current, and the battery voltage that are measured, in chronological order;
estimating the current estimated charge capacity of the secondary battery;
detecting occurrence of a conforming discharge period in which a conforming discharge that conforms to a predetermined set of discharge conditions is performed, using the battery temperature, the battery current, and the battery voltage;
obtaining a measured voltage drop amount that appears during the detected conforming discharge period, using the battery voltage;
obtaining an estimated voltage drop amount that is estimated to appear during the conforming discharge period, using the estimated charge capacity, a duration of the conforming discharge period, the battery temperature during the conforming discharge period, and the battery current flowing during the conforming discharge period; and
determining whether there is abnormal deterioration in the secondary battery, from the measured voltage drop amount and the estimated voltage drop amount.

10. The method according to claim 9, wherein obtaining the estimated voltage drop amount includes obtaining a linear function equation in advance using, as a variable, an average C-rate that is an average of a C-rate obtained by dividing the battery current by the estimated charge capacity over the conforming discharge period, and obtaining the estimated voltage drop amount by using the linear function equation.

11. The method according to claim 9, wherein determining whether there is abnormal deterioration in the secondary battery comprises obtaining an index of a deviation state between the estimated voltage drop amount and the measured voltage drop amount, and determining whether there is the abnormal deterioration based on the obtained index of the deviation state.

12. The method according to claim 10, wherein determining whether there is abnormal deterioration in the secondary battery comprises obtaining an index of a deviation state between the estimated voltage drop amount and the measured voltage drop amount, and determining whether there is the abnormal deterioration based on the obtained index of the deviation state.

13. The method according to claim 9, wherein the conforming discharge performed during the detected conforming discharge period is a high-current conforming discharge in which the battery current of 75 A or more on average flows.

14. The method according to claim 10, wherein the conforming discharge performed during the detected conforming discharge period is a high-current conforming discharge in which the battery current of 75 A or more on average flows.

15. The method according to claim 11, wherein the conforming discharge performed during the detected conforming discharge period is a high-current conforming discharge in which the battery current of 75 A or more on average flows.

16. The method according to claim 12, wherein the conforming discharge performed during the detected conforming discharge period is a high-current conforming discharge in which the battery current of 75 A or more on average flows.
